(19) United States
(12) Patent Application Publication
(10) Pub. No.: US 2012/0285533 A1
(43) Pub. Date: Nov. 15, 2012

(54) Construction material structure for use with solar power

(76) Inventor: Yaue-Sheng Chang, Taoyuan Hsien (TW)

(21) Appl. No.: 13/107,909

(22) Filed: May 14, 2011

(51) Int. Cl. H01L 31/0203

(52) U.S. Cl. 136/259

(57) ABSTRACT

A construction material structure for use with solar power includes a panel having an outer top side provided thereon with an adhesive element and connected to a bottom side of at least one solar cell via the adhesive element. The panel is a baked enamel steel plate, an aluminum plate, or a plastic plate. A thermal insulation element is disposed on an inner bottom side of the panel. The thermal insulation element is made of polyurethane (PU) foam or gypsum. The adhesive element is an Ethylene Vinyl Acetate (EVA) film or a Polyvinyl Butyral (PVB) film. Another adhesive element is disposed on a top side of the at least one solar cell. A high-transparency high-light-concentration film is disposed on the another adhesive element. A coarse face including projections is disposed on an outer surface of the high-transparency high-light-concentration film. The high-transparency high-light-concentration film is made of Teflon (TEFZEL), Polyester (PET) or Polycarbonate (PC).

### BACKGROUND OF THE INVENTION

1. Field of the Invention

The present invention relates to construction material structures for use with solar power, and more particularly, to a construction material structure adapted for use with solar power and characterized in that a solar cell is directly fixed to the construction material.

2. Description of the Prior Art

Conventional solar modules are assembled one by one before being installed on a roof. Due to the aforesaid conventional structure, the general public mistake solar modules for special devices to the detriment of promoting solar modules. Considering that the man in the street is much more likely to visit a construction material shop than a power generation equipment factory, the inventor of the present invention conducted research with a view to providing a product for meeting the actual demand better and eradicating the long-time misunderstanding of the use of solar modules.

### BRIEF SUMMARY OF THE INVENTION

It is a primary objective of the present invention to provide a construction material structure for use with solar power so as to integrate the solar power generation function into the inherent functions of construction materials by disposing solar power equipment on the construction materials directly and incorporating the design stage and the application stage of the solar power equipment into the construction stage, the renovation stage, and the expansion stage or a house, thereby effectuating environmental protection, power saving, and power utilization naturally.

In order to achieve the above and other objectives, the present invention provides a construction material structure for use with solar power. The construction material structure for use with solar power comprises a panel having an outer top side provided thereon with an adhesive element and connected to a bottom side of at least one solar cell via the adhesive element. The panel is a baked enamel steel plate, an aluminum plate, or a plastic plate. A thermal insulation element is disposed on an inner bottom side of the panel. The thermal insulation element is made of polyurethane (PU) foam or gypsum. The adhesive element is an Ethylene Vinyl Acetate (EVA) film or a Polyvinyl Butryral (PVB) film. The at least one solar cell has a top side provided thereon with another adhesive element and connected to a high-transparency high-light-concentration film via the another adhesive element. A coarse face including projections is disposed on an outer surface of the high-transparency high-light-concentration film. The high-transparency high-light-concentration film is made of Teflon (TEFZEL), Polyester (PET) or Polycarbonate (PC).

### BRIEF DESCRIPTION OF THE SEVERAL VIEWS OF THE DRAWINGS

In order to enable examiners to gain insight into the techniques and means employed to achieve the anticipated objectives or the present invention and the effect thereof, the objectives, features, and advantages of the present invention are hereunder illustrated with a preferred feasible embodiment in conjunction with the accompanying drawings, in which:

FIG. 1 is a cross-sectional view of the present invention;

FIG. 2 is a perspective view of a wall board implemented according to the present invention;

FIG. 3 is a perspective view of a corrugated board implemented according to the present invention; and

FIG. 4 is a cross-sectional view of a coarse face of a high-transparency high-light-concentration film the present invention.

### DETAILED DESCRIPTION OF THE EMBODIMENT OF THE INVENTION

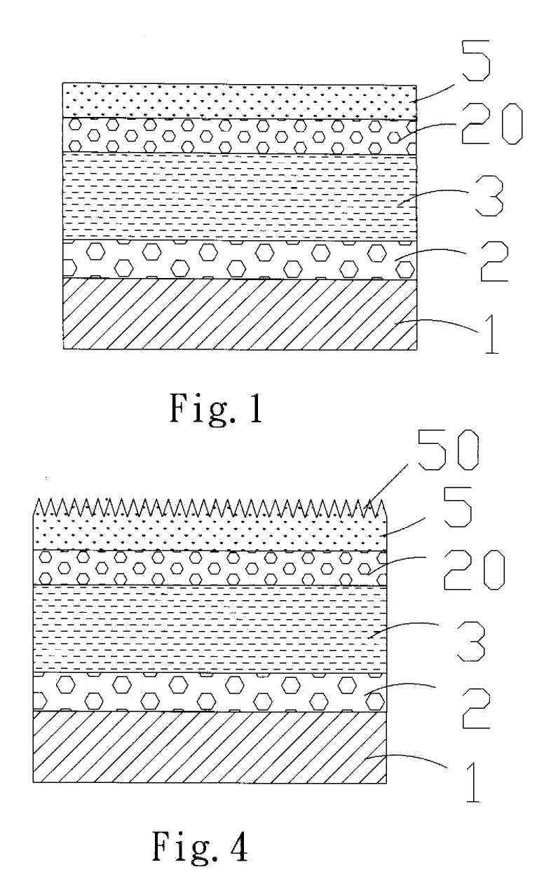

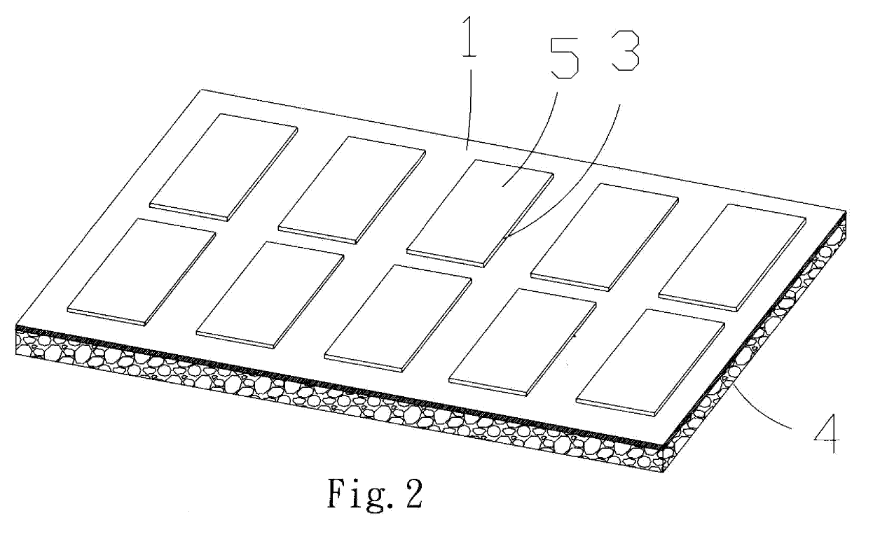

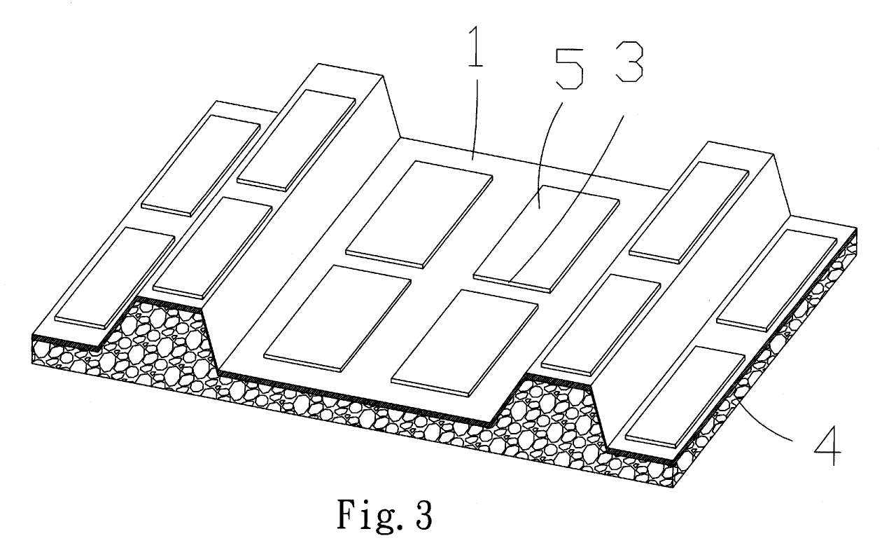

Referring to FIG. 1 through FIG. 4, the present invention provides a construction material structure for use with solar power. The construction material structure for use with solar power comprises a panel 1. The panel 1 has an outer top side provided thereon with an adhesive element 2 and connected to a bottom side of at least one solar cell 3 via the adhesive element 2. The panel 1 is a baked enamel steel plate, an aluminum plate, or a plastic plate. A thermal insulation element 4 is disposed on an inner bottom side of the panel 1. The thermal insulation element 4 is made of polyurethane (PU) foam or gypsum. The adhesive element 2 comes in the form of an Ethylene Vinyl Acetate (EVA) film or a Polyvinyl Butyral (PVB) film. Another adhesive element 20 is disposed on a top side of the at least one solar cell 3. A high-transparency high-light-concentration film 5 is disposed on the another adhesive element 20. A coarse face 50 comprising projections (that is, the spiky projections shown in FIG. 4, though not limited thereto) is disposed on an outer surface of the high-transparency high-light-concentration film 5. The high-transparency high-light-concentration film is made of Teflon (TEFZEL), Polyester (PET) or Polycarbonate (PC). FIG. 1 depicts the basic structure or the present invention. FIG. 2 shows a wall board or a top board. FIG. 3 shows a corrugated board. At present, corrugated boards are in wide use with various roofs. Given the construction material structure for use with solar power according to the present invention, it is not necessary to change the structure of a roof in order to install solar power generation equipment on the roof; instead, the house can be powered by solar energy as soon as the roof is installed and wired. The solar cells 3 each comprise a photovoltaic conversion element for converting light energy into electrical energy to be conveyed by electrical wires. An electrical wire protrudes from each of the solar cells 3. The electrical wires are connected in series and in parallel such that appropriate power is supplied to various electrical appliances.

Regarding the aforesaid structure, the present invention embodies the concept of integral formation of a unitary unit, dispenses with an external frame and related fixing apparatuses otherwise disclosed in the prior art, and couples a solar cell and a construction material together, such that the resultant product functions as a solar tile for use with a road surface as well as various venues, thereby enabling the general public to become renewable energy users and save various fossil energy. Accordingly, the present invention has high industrial applicability and is utterly different from the prior art.

The aforesaid preferred embodiment or the present invention is described in detail and illustrated with drawings. However, persons skilled in the art should understand that the preferred embodiment is illustrative of the present invention only, but should not be interpreted as restrictive of the scope or the present invention. Hence, all equivalent modifications and changes made to the aforesaid embodiment and the structure described therein should fall within the scope of the present invention. Accordingly, the legal protection for the present invention should be defined by the appended claims.

What is claimed is:

1. A construction material structure for use with solar power, comprising a panel having an outer top side provided thereon with an adhesive element and connected to a bottom side of at least one solar cell via the adhesive element, the at least one solar cell having a top side provided thereon with another adhesive element and connected to a high-transparency high-light-concentration film via the another adhesive element.

2. The construction material structure for use with solar power of claim 1, wherein the panel is one of a baked enamel steel plate, an aluminum plate, and a plastic plate.

3. The construction material structure for use with solar power of claim 1, wherein a thermal insulation element is disposed on an inner bottom side of the panel.

4. The construction material structure for use with solar power of claim 3, wherein the thermal insulation element is made or one of polyurethane (PU) foam and gypsum.

5. The construction material structure for use with solar power of claim 1, wherein the adhesive element is an Ethylene Vinyl Acetate (EVA) film or a Polyvinyl Butyral (PVB) film.

6. The construction material structure for use with solar power of claim 1, wherein a coarse face comprising projections is disposed on an outer surface of the high-transparency high-light-concentration film.

7. The construction material structure for use with solar power of claim 1, wherein the high-transparency high-light-concentration film is made of Teflon (TEFZEL), Polyester (PET) or Polycarbonate (PC).
